(19) United States
(12) Patent Application Publication
(10) Pub. No.: US 2006/0145184 A1
(43) Pub. Date: Jul. 6, 2006

(54) Reverse MOS (RMOS) transistor, and methods of making and using the same

(76) Inventor: Sang Soo Song, Seoul (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/324,171

(22) Filed: Dec. 29, 2005

(30) Foreign Application Priority Data
Dec. 30, 2004 (KR) 10-2004-0117520

(51) Int. Cl. H01L 29/74

(52) U.S. Cl. 257/121; 438/221; 438/197

(57) ABSTRACT

A metal-oxide-semiconductor transistor having a reverse current control mechanism (RMOS transistor) is described. The RMOS transistor generally includes a semiconductor substrate, a gate electrode on an oxide layer on the substrate, source and drain electrodes at opposite sides of the gate electrode, and a carrier region having a carrier with a type opposite to that of the substrate, in the substrate below the gate, source and drain electrodes. The carrier region maintains a turn-on state where current can flow between drain and source regions without a bias voltage applied to the gate electrode. When a bias voltage is applied to the gate electrode, the carrier region is electrically disconnected to turn off the transistor.

### CROSS REFERENCE TO RELATED APPLICATIONS

This U.S. non-provisional application claims priority under 35 U.S.C. §119 from Korean Patent Application No. 2004-117520, which was filed in the Korean Intellectual Property Office on Dec. 30, 2004, the contents of which are incorporated by reference herein in its entirety.

### BACKGROUND OF THE INVENTION

1. Field of the Invention

The present invention relates generally to semiconductor transistors and, more particularly, to transistors having a reverse electrical current control mechanism, compared to conventional metal oxide semiconductor (MOS) transistors.

2. Description of the Related Art

In general, MOS transistors (for example, N-type MOS transistors) consist of or include heavily doped (e.g., N+) source and drain regions diffused or implanted into a lightly doped (e.g., P-type) substrate, and a thin oxide layer separates a metal or polysilicon gate from the substrate. The operation of the NMOS transistor is controlled by a voltage applied to the gate, which controls the formation of an N-channel between the source and drain regions. No current flows from drain to source without a conducting N-channel, since the drain-substrate-source combination includes oppositely doped (or directed) PN junctions in series. When a positive voltage greater than a threshold voltage is applied to the gate, negative charges are induced in the underlying substrate, allowing electrical current flowing from drain to source.

As the manufacturing technologies for semiconductor transistors have advanced, the size of the MOS transistor is greatly reduced and thus the gate length, thickness and length of the gate oxide, depth of the source and drain regions, and operating voltage of the MOS transistors are also reduced. When the gate length and the thickness of the gate oxide reduce to lower than critical values, the existing MOS transistor structures are approaching a number of fundamental limits. State-of-the-art fabrication technologies have progressed to achieve a gate length of 100 nm and a gate oxide thickness of 2 nm, which amounts to a thickness of less than ten atoms. With the atomic dimensions of the gate oxide, the gate leakage currents can be larger than desired due to direct tunneling. Thus, in some applications, a thin gate oxide cannot be used for dielectric material any longer. For preventing direct tunneling current and a reduction of gate capacitance due to gate poly depletion, higher dielectric constant (k) materials such as SiON, Al₂O₃, Ta₂O₅, ZrO₂, and HfO₂ have been developed as a new gate dielectric. Challenging aspects in developing the new gate dielectric materials include features of the interface with the bulk semiconductors (e.g., single-crystal silicon substrate or polysilicon gate) and traditional high-temperature processes used for manufacturing the LSI devices. Further, when the gate length is reduced to below 30 nm, the gate voltage may not adequately control the channel, and thus, a conventional MOS structure may not provide suitable transistor operations.

### SUMMARY OF THE INVENTION

It is therefore a purpose of the present invention to introduce a new MOS transistor structure suitable for atomic level dimensions (e.g., devices having a gate dielectric thickness of about 10 atoms or less, gate lengths of about 30 nm or less, etc.).

Another purpose of the present invention is to provide a new MOS transistor structure that can operate without or beyond certain fundamental limits.

According to one exemplary embodiment of the present invention, control of channel current is opposite to the traditional approach. The MOS transistor of the present invention is the same as the conventional transistor in that it comprises, consists essentially of or consists of a metal- (or silicon-) oxide-semiconductor stack, and the majority carriers in the conducting channel define the transistor type as N or P. In terms of the opposite current control, the MOS transistor of the present invention is referred to as a reverse MOS transistor (RMOS transistor).

In the RMOS transistor, the channel between the drain and source always exists (in one aspect, the ‘carrier region’), and a voltage is applied to the gate to break (or render nonconductive) the carrier region. In other words, the gate voltage is used to turn off the RMOS transistor (or to electrically isolate the source and drain from each other, or reduce the transconductance of the channel between the drain and source), rather than to turn on the transistor as in the conventional MOS transistor. The channel region of the RMOS transistor has been doped with the same carrier as the drain and source region carrier and/or dopant(s), so that the transistor maintains the turn-on state without a gate voltage being applied.

### BRIEF DESCRIPTION OF THE DRAWINGS

FIG. 1 is a cross-sectional view of a P-type RMOS transistor according to the present invention.

FIGS. 2a and 2b are cross-section views for illustrating the turn-off operation of the P-type RMOS transistor.

FIG. 3 is a graph showing the effect of a voltage applied to the gate of a P-type RMOS transistor as a function of time.

FIG. 4 is a cross-sectional view of an N-type RMOS transistor according to the present invention.

FIGS. 5a and 5b are cross-sectional views for illustrating the turn-off operation of the N-type RMOS transistor.

FIG. 6 is a graph showing the effect of a voltage applied to the gate of an N-type RMOS transistor as a function of time.

### DETAILED DESCRIPTION OF EXEMPLARY EMBODIMENTS OF THE INVENTION

An exemplary, non-limiting embodiment of the present invention will now be described more fully hereinafter with reference to the accompanying drawings. This invention may, however, be embodied in many different forms and should not be construed as limited to the exemplary embodiment(s) set forth herein. Rather, the disclosed embodiment(s) are provided to more fully convey the scope of the invention to those skilled in the art. The principles and features of this invention may be employed in varied and numerous embodiments without departing from the scope of the invention.

It is noted that well-known structures and processes are not described or illustrated in detail to avoid obscuring the essence of the present invention. It is also noted that the figures may not be drawn to scale. Rather, for simplicity and clarity of illustration, the dimensions of some of the elements may be exaggerated relative to other elements.

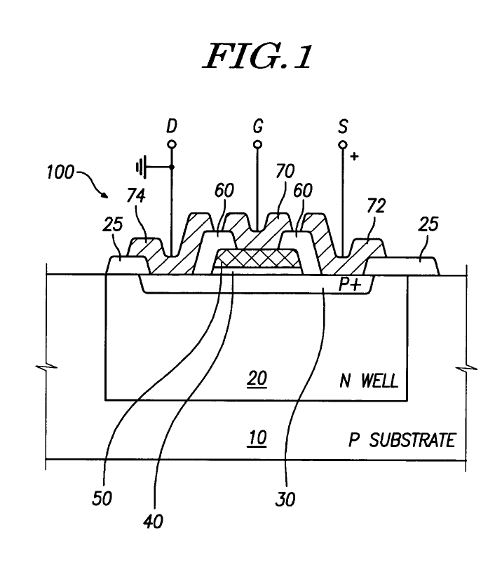

FIG. 1 is a cross-sectional view of a P-type RMOS transistor 100 according to the present invention.

The P-type RMOS transistor 100 is formed in N-type well 20, which in turn is formed in P-type substrate 10. The active region of a transistor is defined by patterning a field oxide 25 on the substrate 10 (or, alternatively, a shallow trench isolation structure in the substrate 10). Although the field oxide 25 is shown above a planar surface of the substrate 10, it is known that field oxide 25 may be partly or nearly completely below the planar portion of the upper surface of substrate 10. Carrier region 30 doped with carriers having a type (e.g., N or P) opposite to the carriers for the well 200 is formed in the active regions by (e.g., P+) ion implantation or diffusion. The carrier for the carrier region 30 includes impurities (e.g., boron) employed in forming source and drain regions in the conventional N-type MOS transistor, and a doping density of the P+ carrier regions 30 is e.g., greater than 10¹⁵ cm^{-3.}

After forming the P+ carrier region 30, a gate oxide layer 40 is formed on the substrate surface, and a gate material 50 is deposited thereon. Then, an interlayer dielectric 60 is deposited and patterned to form a contact hole that exposes areas of the gate electrode and source and drain regions, and the gate electrode 70, source electrode 72 and drain electrode 74 are formed by a conventional metallization process (e.g., tungsten plug or contact formation, deposition and patterning of aluminum metallization, etc.).

The P-type RMOS transistor 100 of FIG. 1 has no bias voltage applied to the gate electrode 70, while positive voltage is applied to the source electrode 72 and the drain electrode 74 is electrically interconnected to ground potential. For example, although the gate and/or gate electrode is typically considered to be a “high impedance” node in an electrical circuit, the condition or state in which the gate and/or gate electrode has no bias applied to it may be a condition in which a ground potential (e.g., 0 volts) is applied to the gate, or in some embodiments, it can be considered a “floating” or “high Z” state. P-type carriers supplied through the source electrode 72 flow to the source electrode 72 through the P-type carrier region 30 formed under the source electrode 72, the gate 50 and the drain electrode 74. Therefore, the RMOS transistor 100 keeps the turn-on state where current flows between P-type source and drain regions without any bias voltage being applied to the gate 50 and/or gate electrode 70.

Although the carrier region 30 is shown in FIG. 1 to have uniform depth from the source to drain regions, the portion of carrier region 30 under the gate material 50 may be shallower than the depths of the source and drain regions. The difference of the depth of carrier region 30 may be determined by the gate voltage to turn-off the RMOS transistor, the doping density of the carrier region, the thickness of gate oxide and the characteristics of the turn-off voltage. For reducing the depth of carrier region under the gate material, the doping for the carrier region may be performed two times: first, relatively shallow doping for the carrier region under the gate material; and second, relatively deep doping for the source and drain regions. For example, the shallow doping for the carrier region under the gate material can comprise implanting ions of an appropriate carrier type into the entire active area of a transistor at a relatively low energy, and the relatively deep doping for the source and drain regions can comprise implanting ions of the same carrier type into the source and drain regions of a transistor (using the gate 50 [which may further comprise a sidewall spacer, not shown] as an implant mask) at a relatively high energy. Thus, the P+carrier region 30 under the source, gate and drain electrodes 72, 50 and 74 is not limited to a uniform depth (although such a carrier region 30 having a uniform depth can be made in a single ion implantation step [typically comprising photolithographic radiation and patterning of a photoresist to form an implant mask, implanting dopant ions comprising boron into the well 20 to form carrier region 30, removing the implant mask, and annealing] and can eliminate any issues that could arise from poor alignment between the relatively shallow implant under the gate material and the relatively deep implant for the source and drain regions, thereby possibly enabling a smaller device size).

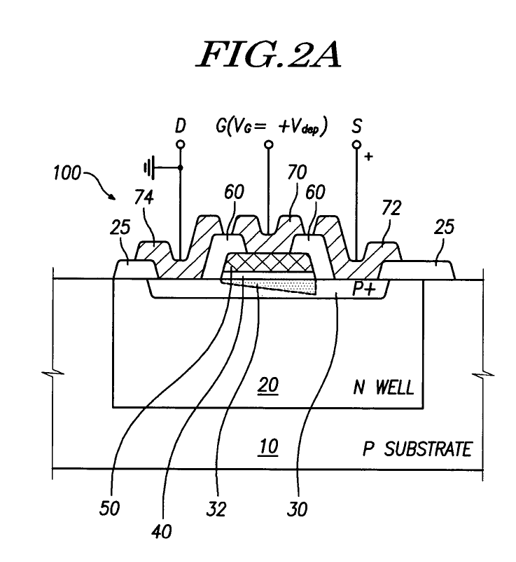

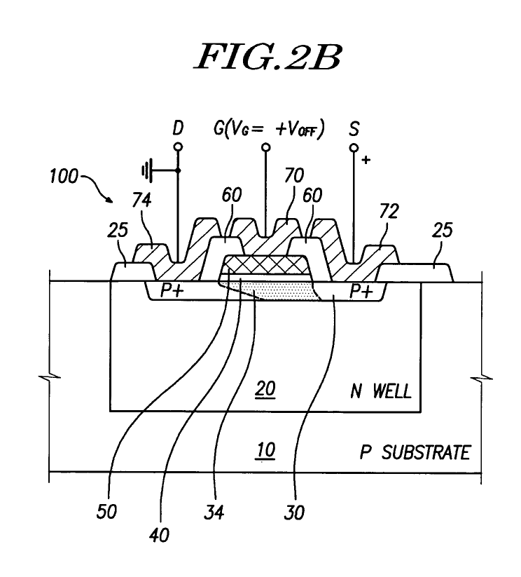

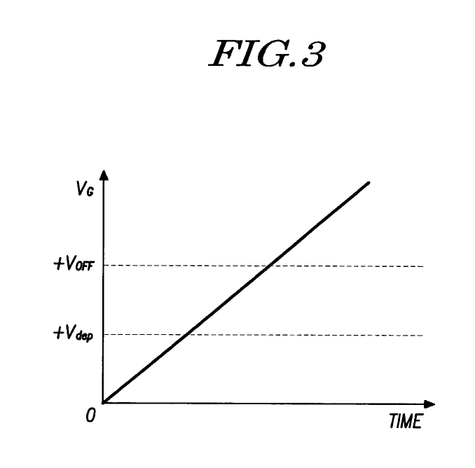

FIGS. 2a and 2b are cross-sectional views for illustrating the turn-off operation of the P-type RMOS transistor shown in FIG. 1. When bias voltage VG is applied to gate electrode 70 of the RMOS transistor 100, a depletion region 32 (see FIG. 2a) and an inversion region 34 (see FIG. 2b) are formed in the carrier region 30 to turn-off the RMOS transistor 100.

Referring to FIG. 2a, positive voltage +V_{dep} is applied to the gate electrode 70, and P-type carriers (holes) in the carrier region 30 below the gate material 50 are electrostatically repelled from the substrate surface and driven into the well 20 to form the depletion region 32. Voltage +V_{dep} is generally greater than a threshold voltage below which no depletion region forms. The depletion region 32 is thicker in the source region due to the positive voltage applied to the source electrode 72.

When the gate voltage increases from +V_{dep} to +V_{OFF}, electrons in the N-type well 200 move toward a region under the gate material 50 and a portion of the P+ carrier region under the gate material 50 is converted to N-type to form the inversion region 34, as shown in FIG. 2b. Therefore, the carrier region 30 between the source and drain electrically disconnects or isolates the source from the drain, and the RMOS transistor 100 is turned-off. The discontinuity of the carrier region 30 starts at the drain region and progresses toward the source region.

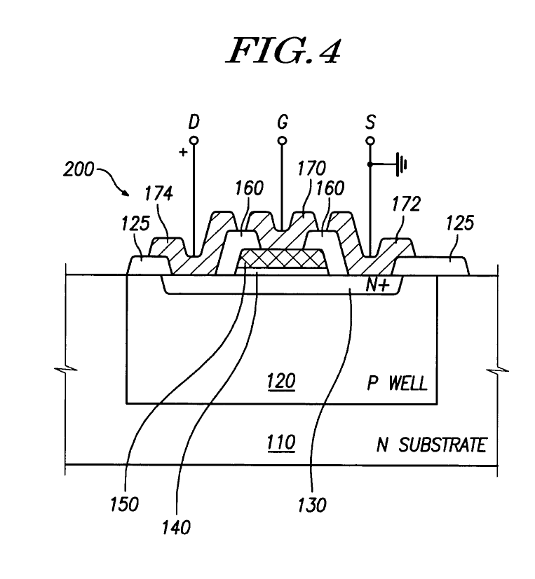

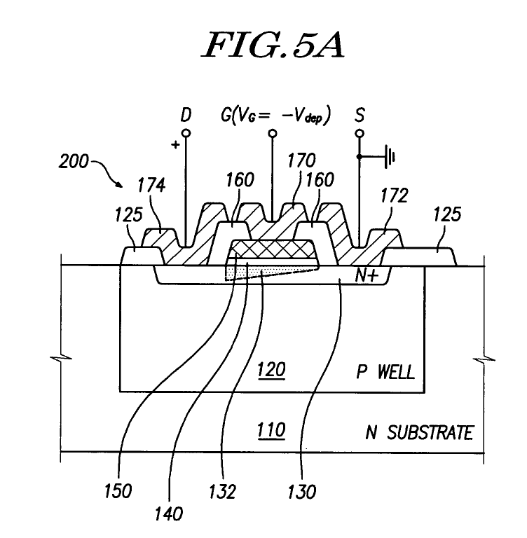

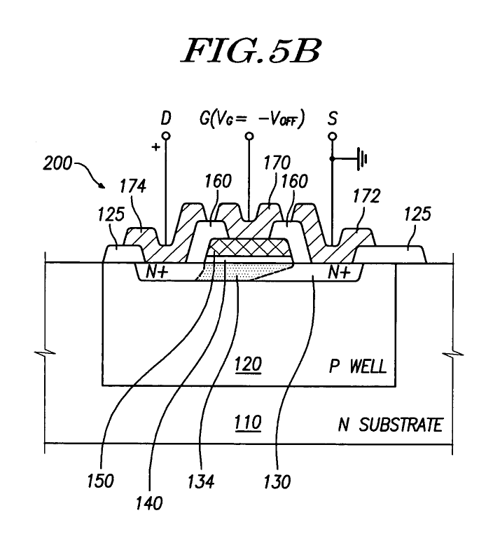

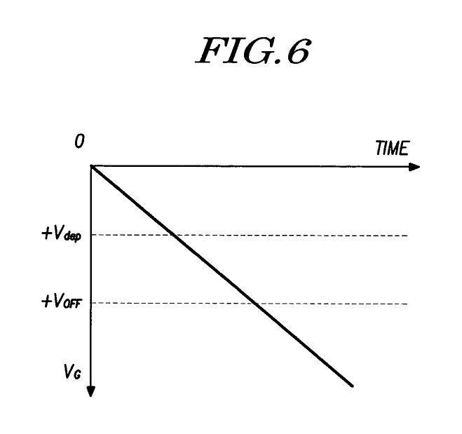

FIG. 4 is a cross-sectional view of an N-type RMOS transistor 200 according to the present invention, and FIGS. 5a and 5b are cross-sectional views for illustrating the turn-off operation of N-type RMOS transistor 200 of FIG. 4 by applying a bias voltage as shown in FIG. 6 to the gate electrode 170.

When compared to the P-type RMOS transistor explained above, the N-type RMOS transistor 200 shown in FIGS. 4 and 5 has differences in that the type of substrate 110, well 120, carrier region 130, depletion region 132 and inversion region 134 are the opposite of the P-type RMOS transistor, and the voltages applied to the source, gate and drain are also the opposite (or are complementary to those of the P-type RMOS transistor). In other words, field oxide layer 125, gate oxide 140, gate material 150, interlayer dielectric 160 and metal electrodes 170, 172 and 174 of the P-type RMOS transistor may be the same as in the P-type RMOS transistor (although the dopant in the gate material 150 of the N-type RMOS transistor 200 may be the opposite type from that of the P-type RMOS transistor), and hence detailed explanations thereof are omitted.

According to the present invention, the carrier region that makes the current flow between the drain and source regions exists without any bias voltage applied to the gate 150, and the gate voltage is controlled to turn-off the transistor. Therefore, the gate can perform its intended operation so long as it has dimensions (e.g., length and/or width) sufficient to receive the applied voltage. That is to say, control of transistor operations are possible in the present invention, even with an extremely short gate structure (e.g., less than or equal to about 30 nm).

Further, the RMOS transistor structure disclosed herein does not have certain problems that may arise in conventional MOS transistors, such as hot carrier effects and short channel effects.

While this invention has been particularly shown and described with reference to an exemplary embodiment thereof, it will be understood by those skilled in the art that various changes in form and details may be made therein without departing from the spirit and scope of the invention as defined by the appended claims.

What is claimed is:

1. A transistor comprising:
a semiconductor substrate;
an oxide layer on the substrate;
a gate on the oxide layer;
source and drain electrodes at opposite sides of the gate; and
a carrier region doped with a carrier having a type opposite to that of the substrate, in the substrate below the gate and the source and drain electrodes;
said carrier region allowing current to flow between the drain and source electrodes when no bias voltage is applied to the gate (and/or a corresponding gate electrode), and disabling current from flowing when a bias voltage is applied to the gate (and/or the corresponding gate electrode).

2. The transistor of claim 1, wherein the carrier region has a shallow portion below the gate electrode, the shallow portion having a depth smaller than other portions of the carrier region.

3. The transistor of claim 1, wherein the semiconductor substrate comprises a single crystal silicon wafer.

4. The transistor of claim 3, wherein the semiconductor substrate comprises a P-doped single crystal silicon wafer having an N-well therein.

5. The transistor of claim 4, wherein the carrier region comprises a P-type dopant, and the transistor further comprises P-type source and drain terminals in the N-well, below the source and drain electrodes.

6. The transistor of claim 5, wherein the carrier region under the gate material comprises a relatively shallow ion implant, and the source and drain terminals each comprise a relatively deep ion implant.

7. The transistor of claim 3, wherein the semiconductor substrate comprises an N-doped single crystal silicon wafer having a P-well therein.

8. The transistor of claim 7, wherein the carrier region comprises an N-type dopant, and the transistor further comprises N-type source and drain terminals in the P-well, below the source and drain electrodes.

9. The transistor of claim 8, wherein the carrier region under the gate material comprises a relatively shallow ion implant, and the source and drain terminals each comprise a relatively deep ion implant.

10. The transistor of claim 1, wherein the semiconductor substrate further comprises source and drain regions doped with a carrier having a type opposite to that of the substrate, in the substrate below the source and drain electrodes.

11. A method of making a transistor, comprising:
doping at least a channel region in an active area of a semiconductor substrate with a carrier having a type opposite to that of the active area;
forming an oxide layer on the substrate;
forming a gate on the oxide layer; and
forming a gate electrode on the gate and source and drain electrodes at opposite sides of the gate.

12. The method of claim 11, wherein the carrier region is doped sufficiently to allow current to flow between the drain and source terminals when no bias voltage is applied to the gate, and to disable current from flowing when a bias voltage is applied to the gate electrode.

13. The method of claim 11, further comprising forming a well in the substrate, prior to doping the channel region.

14. The method of claim 11, further comprising forming an isolation structure on and/or in the substrate to define the active area.

15. The method of claim 11, further comprising forming source and drain terminals in the substrate below the source and drain electrodes, the source and drain terminals having a same carrier type as that of the channel region.

16. The method of claim 15, wherein doping at least the channel region comprises implanting ions into the active area at a relatively low energy, and forming the source and drain terminals comprises implanting ions into in source and drain regions of the substrate at a relatively high energy.

17. A method of operating a MOS transistor, comprising:
applying a bias voltage to a gate and/or gate electrode of the transistor to turn off the transistor or reduce its transconductance, the transistor comprising an oxide layer on a semiconductor substrate, the gate on the oxide layer, source and drain electrodes at opposite sides of the gate, and a carrier region doped with a carrier having a type opposite to that of the substrate, the carrier region in the substrate below the gate and the source and drain electrodes; and
not applying the bias voltage to a gate and/or gate electrode of the transistor to disable current from flowing between the drain and source electrodes.
